(19) United States
(12) Patent Application Publication
(10) Pub. No.: US 2008/0231143 A1
(43) Pub. Date: Sep. 25, 2008

(54) PIEZOELECTRIC MOVEMENT DEVICE

(75) Inventors: Julian Chen, White Plains, NY (US); Oswald Pietzsch, Hamburg (DE); Daniel Haude, Hamburg (DE)

Correspondence Address: MICHAUD-DUFFY GROUP LLP, 306 INDUSTRIAL PARK ROAD, SUITE 206, MIDDLETOWN, CT, 06457, US

(73) Assignee: UNIVERSITAT HAMBURG, Hamburg (DE)

(21) Appl. No.: 12/107,941

(22) Filed: Apr. 23, 2008

Related U.S. Application Data
(63) Continuation of application No. PCT/EP2006/010220, filed on Oct. 24, 2006.

(30) Foreign Application Priority Data
Oct. 28, 2005 (DE) 10 2005 052 132.0

(51) Int. Cl. H01L 41/09

(52) U.S. Cl. 310/328

(57) ABSTRACT

The invention relates to a piezoelectric movement device, in particular a motor, with a piezoelectric apparatus, which has a middle area and two end areas, and with a movement body, which is mounted on or in a mount or the piezoelectric apparatus, wherein one end area is designed or both end areas are designed to exert a force in the direction of the movement body, in particular diagonally and axially or transversely of the axis to a longitudinal axis of the piezoelectric apparatus, on the movement body. The invention is characterized in that the middle area is a piezoelectric body and the end areas each comprise at least two piezoelectric bodies, which are connected with each other, in particular via contact surfaces.

### CROSS-REFERENCE TO RELATED APPLICATIONS

This application is a continuation of and claims priority to International Patent Application No. PCT/EP2006/010220 filed on Oct. 24, 2006, which claims priority to German Patent Application No.10 2005 052 132.0 filed on Oct. 28, 2005, the subject matter of these patent documents is incorporated by reference herein in its entirety.

### FIELD OF THE INVENTION

The invention relates to a piezoelectric movement device, in particular a motor, with a piezoelectric apparatus, which has a middle area and two end areas, and with a movement body, which is mounted on or in a mount or the piezoelectric apparatus, wherein one end area is designed or both end areas are designed to exert a force in the direction of the movement body, in particular transversely of the axis to a longitudinal axis of the piezoelectric apparatus, on the movement body.

### BACKGROUND OF THE INVENTION

This type of piezoelectric movement device is known. It concerns the so-called inchworm made by the company EXFO, previously Burleigh Instruments, Inc, East Worchester, N.Y.

The inchworm is for example described in detail in U.S. Pat. No. 3,902,084 A and U.S. Pat. No. 3,902,085 A. It concerns a piezoelectric movement device with a piezo tube or a piezoelectric apparatus, in which a shaft or a movement body is inserted in the tube. In order to move the shaft or the movement body in a translatory manner, one end area of the piezo tube is reduced through the application of a voltage from the inside diameter so that a clamping of the movement body takes place. Subsequently, a middle area of the piezo tube is expanded or contracted. It is assumed for this example that the middle area is lengthened. The other end area is then also reduced from the inside diameter through the application of a voltage in order to clamp the movement body. The first end area is then opened and the middle area is contracted in the longitudinal and axial direction in order to thus enable a movement of the movement body in the longitudinal direction. The first end area is then subsequently reduced again in the radial direction or diagonally to the longitudinal and axial direction (which means transversely to the axial direction), i.e. the internal diameter is reduced in order to clamp the movement body and the second end area is opened again or the clamping is ended so that the movements can start from the beginning. The overall result is a stepwise movement of the movement body in the longitudinal and axial direction.

The inchworm according to these two U.S. patent documents is very stable, but it can also be improved. For one, the displacement in the radial direction and the diameter reduction during the clamping of the movement body is relatively small so that a secure clamping cannot be ensured in the case of low temperatures. Moreover, the piezo material on the movement body rubs so that relatively high wear and tear results. In the end, only a translatory movement is possible.

### SUMMARY OF THE INVENTION

The object of the present invention is to expand the area of application of a corresponding piezoelectric movement device and to design in a more secure manner the handling of a movement body of the piezoelectric movement device.

This object is solved through a piezoelectric movement device, in particular a motor, with a piezoelectric apparatus, which has a middle area and two end areas, and with a movement body, which is mounted on or in a mount or the piezoelectric apparatus, wherein one end area is designed or both end areas are designed to exert a force in the direction of the movement body, in particular transversely of the axis and axially to a longitudinal axis of the piezoelectric apparatus, on the movement body, wherein the middle area is a piezoelectric body and the end areas each comprise two piezoelectric bodies, which are connected with each other, in particular via contact surfaces.

Through the piezoelectric movement device according to the invention and in particular due to the fact that the end areas each comprise two piezoelectric bodies, which are connected with each other via contact surfaces, a much larger force can be exerted on the movement body, since a greater displacement in the direction of the movement body can be achieved through a type of two-element piezo body, which is named “bimorph” in the literature. This increases in particular the area of application of the piezoelectric movement device even at low temperatures, since the reduction of the piezoelectric coefficients at low temperatures can be more than counterbalanced by the stronger deflection effect and thus the stronger force exertion on the movement body.

Within the framework of the invention, the term piezo effect is also understood to include the electrostriction effect, i.e. the effect opposite the piezo effect. A piezoelectric movement device is thus also in particular a movement device, which occurs due to movements of piezoelectric crystals or a piezoelectric material based on the application of an electrical potential or a voltage.

Within the framework of the invention, the longitudinal axis is aligned along the longest expansion of the piezoelectric apparatus. This does not have to be arranged in the middle point of the plane, which cuts the piezoelectric apparatus diagonally or transversely to the longitudinal axis, but rather can also be arranged for example on a lateral surface or shall surface of a piezo tube, which can be part of the piezoelectric apparatus. The longitudinal axis can also be a symmetrical axis.

The measurement standards or normals of the contact surfaces are preferably arranged mainly parallel to the direction of the exerted force. This results in a classical two-element body or a bimorph. This can be understood as a type of sandwich, wherein an adhesive can be provided between the two piezo bodies.

An electrode is preferably arranged between the two piezoelectric bodies of the end areas. Furthermore, electrodes are preferably arranged on the opposite-lying sides of the piezoelectric body, i.e. the surfaces, which are arranged parallel to the contact surface.

A particularly preferred embodiment, which has an independent inventive character, is then present when an intermediate body made of a different material than the piezoelectric body is provided on at least one piezoelectric body of an end area on the surface, which is arranged next to the movement body. This other material can for example be abrasion-resistant and/or have a low friction with the movement body so that a much lower wear and tear occurs on the interface between the movement body and the intermediate body during contact of the intermediate body with the movement body instead of the contact of a piezo material with the movement body. This can considerably increase the service life of the piezoelectric movement device.

The intermediate body is preferably connected with a piezoelectric body and is especially preferably glued.

An especially elegant solution to the object is then present when the mount is part of the piezoelectric apparatus. This can be the case for example when the piezoelectric apparatus comprises a piezoelectric tube or two parallel piezoelectric rods, which are connected to the respective longitudinal and axial lateral surfaces by another material or piezoelectric material, are provided and the movement body is arranged within this type of piezoelectric apparatus. The piezoelectric apparatus is preferably a long hollow body that is open at the end areas. In particular, the hollow body is preferably a, in particular cylindrical, tube.

The object is solved extremely efficiently in that the piezoelectric apparatus is slitted longitudinally and axially in the end areas. Through the provision of slits in the end areas, in particular in the case of a hollow body, the stronger displacement of the two-layer piezo body can be transferred very well to the movement body, so that a correspondingly large holding force is enabled. The provision of slits in the end area of a hollow body or a tube also has an independent inventive character.

The object is furthermore solved through a piezoelectric movement device, wherein a piezoelectric apparatus is provided, which has a middle and two end areas and a movement body, which is mounted on or in a mount or the piezoelectric apparatus, wherein an end area is designed or both end areas are designed to exert a force in the direction of the movement body, in particular diagonally and axially or transversely of the axis to a longitudinal axis of the piezoelectric apparatus, on the movement body, wherein the middle area of the piezoelectric apparatus has at least one electrode, which is arranged obliquely to the longitudinal axis of the piezoelectric apparatus.

Through the provision of this type of obliquely or angular arranged electrode in the middle area, it is possible for the first time to achieve a rotational movement of the movement body and also a translatory movement of the movement body with a corresponding piezoelectric movement device. Within the framework of the invention, oblique arrangement with respect to the longitudinal axis means in particular at an angle to the longitudinal axis preferably between 10° and 80°, even more preferably in the range from 30° to 60° and most preferably in the range of approx. 45°. The angles depend on the length of the middle area longitudinally and axially to the longitudinal axis and the width diagonally or transversely to this or in the case of a tube of the casing width, which, as long as it would be rolled up, would also be arranged transversely of the axis to the longitudinal axis. Furthermore, the angle also naturally depends on how many obliquely arranged electrodes are arranged diagonal to the longitudinal axis of the middle area or the piezoelectric apparatus and the width of the electrode and whether the width remains constant along the diagonal arrangement or increases or decreases.

Several electrodes are preferably arranged obliquely to the longitudinal axis of the piezoelectric apparatus, wherein they are arranged in the longitudinal and axial direction or behind each other or next to each other in a mainly perpendicular manner. Within the framework of the invention, next to each other in a mainly perpendicular manner also means in particular next to each other in a radial manner. If the piezoelectric apparatus has a piezo body in the form of a rod, for example a square-cut rod, then several electrodes can be arranged next to each other mainly perpendicular to the longitudinal axis. In a case, in which the piezoelectric apparatus comprises a hollow body as a piezoelectric body, mainly perpendicular to the longitudinal axis means that it is arranged on the lateral surface, if it is rolled up, next to each other mainly perpendicular to the longitudinal axis. An embodiment is also conceivable in which the electrodes are arranged next to each other in a helical or spiral manner.

The movement body is preferably pivot-mounted. The piezoelectric movement device is especially preferred when at least one electrode is spiral at least in sections. Pairs of obliquely arranged electrodes, which are aligned differently with respect to each other, e.g. opposite the longitudinal axis of the piezoelectric apparatus or tipped or tilted with respect to each other, are preferably provided. At least two electrodes are preferably arranged mirror-symmetrically around a plane, which comprises the longitudinal axis and a common borderline. In this case, it is very easy to achieve a uniform translatory movement of the movement body but an even or equidistant left or right turn can also take place. The piezoelectric movement device is especially simple and elegant when the piezoelectric body of the middle area is one piece with a piezoelectric body of an end area.

The piezoelectric movement device, which was described above, is preferably used to create a translatory and/or rotary movement of the movement body.

Furthermore, a method for the manipulation of a movement body in or on a piezoelectric movement device, which was described above, is specified according to the invention, wherein similar or codirected electrical potentials or voltages are applied to the electrodes of the middle area for the longitudinal and axial expansion or shortening of the middle area of the piezoelectric apparatus. This can result in a translation of the movement body, wherein this represented process step corresponds with the process steps described above, in which the middle area is expanded or shortened longitudinally and axially. Thus, the process steps generally known from the inchworm from the named US documents can be used to complete the method for the manipulation of a movement body.

Furthermore, the object is also solved through a method for the manipulation of a movement body in or on a piezoelectric movement device, which was described above, wherein the electrodes arranged relative to the longitudinal axis in a diagonal or in a mainly perpendicular manner or next to each other radially in the middle area of the piezoelectric apparatus are supplied with locally alternating electrical potentials for the rotation of the movement body.

### BRIEF DESCRIPTION OF THE DRAWINGS

The invention is described below, without restricting the general intent of the invention, based on exemplary embodiments in reference to the drawings. We expressly refer to the drawings with regard to the disclosure of all details according to the invention that are not explained in greater detail in the text. In the figures,

FIG. 1 shows a schematic side view of a piezoelectric movement device according to the state of the art for clarification of the clamping mechanism of the inchworm according to U.S. Pat. No. 3,902,084 A and U.S. Pat. No. 3,902,085 A,

FIG. 2 shows a schematic side view of a piezoelectric movement device according to the invention for clarification of the clamping mechanism,

FIG. 3 shows a schematic sectional representation of part of a piezoelectric movement device according to FIG. 2,

FIG. 4 shows another embodiment of a schematic sectional representation of a piezoelectric movement device according to the invention,

FIG. 5 shows a schematic view of the piezoelectric movement device according to FIG. 4 in a clamped position,

FIG. 6 shows a schematic view from the top of part of the piezoelectric movement device from FIGS. 4 and 5,

FIG. 7 shows another embodiment of a schematic sectional representation of a piezoelectric movement device according to the invention,

FIG. 8 shows a schematic representation of section A1 from FIG. 7,

FIG. 9 shows a schematic sectional representation of another piezoelectric movement device according to the invention,

FIG. 10 shows a schematic representation of section A2 from FIG. 9,

FIG. 11 a schematic three-dimensional representation of part of another piezoelectric movement device according to the invention,

FIG. 12 shows a schematic representation of the rolling up of part of the piezoelectric movement device according to FIG. 11 in one plane,

FIG. 13 a)-d) show voltage-over-time diagrams of the voltages U created on electrodes, and

FIG. 14 shows another lateral surface rolled up into the drawing plane of part of another piezoelectric movement device according to another embodiment according to the invention.

### DETAILED DESCRIPTION OF THE PREFERRED EMBODIMENTS

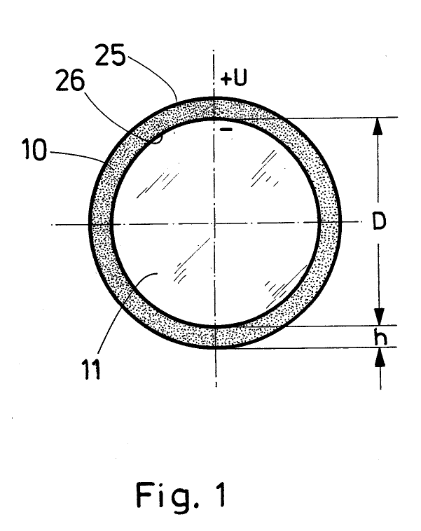

FIG. 1 shows a schematic side view of a known piezoelectric movement device according to U.S. Pat. No. 3,902,084 A and U.S. Pat. No. 3,902,085 A. The purpose of FIG. 1 is to explain the clamping mechanism of the so-called inchworm described in these documents in the case of the piezoelectric movement device according to the state of the art. The inner diameter of the piezo tube 10 is represented by the letter D. The piezo tube 10 has a thickness or height h of the piezo material. A first electrode 25 is shown in the outer casing area and a second electrode 26 is shown in the inner casing area. FIG. 1 also shows a schematic representation of the movement body 11 in the form of a cylindrical shaft. If voltage U is now applied between the first electrode 25 and the second electrode 26, the inner diameter D changes according to the following formula

$$Δ D = {d}_{31} U \frac{D}{h} \qquad ( 1 )$$

When using a soft piezo material, for example PZT (lead zirconate titanate; lead zirconate; lead titanate), for example PZT-5H, which has a large piezoelectric ratio d₃₁ at room temperature of approximately 2.7×⁻⁸ cm/V, and at a relatively high electrical field intensity of 4 kV/cm, the change in the diameter is

ΔD=1.1×10⁻⁴ D (2)

The piezo material PZT-5H or other piezo materials are for example disclosed in Chen, C. J., Introduction to Scanning Tunneling Microscopy, Chapter 9 und Appendix F, Oxford Univ. Press 1993.

For a piezo tube with a diameter of 1 cm, the change in the diameter would mean 1 μm and thus a displacement of the piezo tube towards the movement body 11 of 0.5 μm. In the case of the state of the art, this requires a very high accuracy during production and correspondingly low tolerances. Such low tolerances are necessary in order to enable an effective clamping of the movement body. The tolerances must be considerably smaller than 1 μm. Due to this low expansion, an inchworm is difficult to use at low temperatures. For one, the thermal expansion coefficient for a typical piezoceramic material is 5×10⁻⁶/K. This means that a diameter change of

ΔD=1.3×10⁻³ D (3)

would result in the case of a temperature change of 260 K. If the difference between the thermal expansion coefficient of the piezo tube 10 and the movement body 11 were more than 10%, the clamping mechanism could no longer function correctly. Moreover, the piezoelectric coefficients of the piezo ceramics are considerably reduced at low temperatures. For the material PZT-5H, the piezoelectric coefficient is reduced to 0.5×10⁻⁸ cm/V at 260 K below room temperature. This is ⅕ of the value at room temperature. This results in a reduction in the change of the diameter as follows

ΔD=2×10⁻⁵ D (4)

If the thermal expansion coefficient of the movement body 11 and the piezo material of the piezo tube 10 were more than 2%, the clamping mechanism of the inchworm is no longer guaranteed. Moreover, a relatively high abrasive wear of the piezoelectric material occurs due to the friction with the movement body 11, so that the service life of the inchworm is restricted to 2000 m by the manufacturer, which especially in the case of applications in space or in scanning tunneling microscopes or atomic force microscopes leads to a considerable limitation of the service life of corresponding instruments with an inchworm. Moreover, the relatively low force exerted on the movement body 11 by the inchworm is problematic since the movement body 11 must thus not be too heavy.

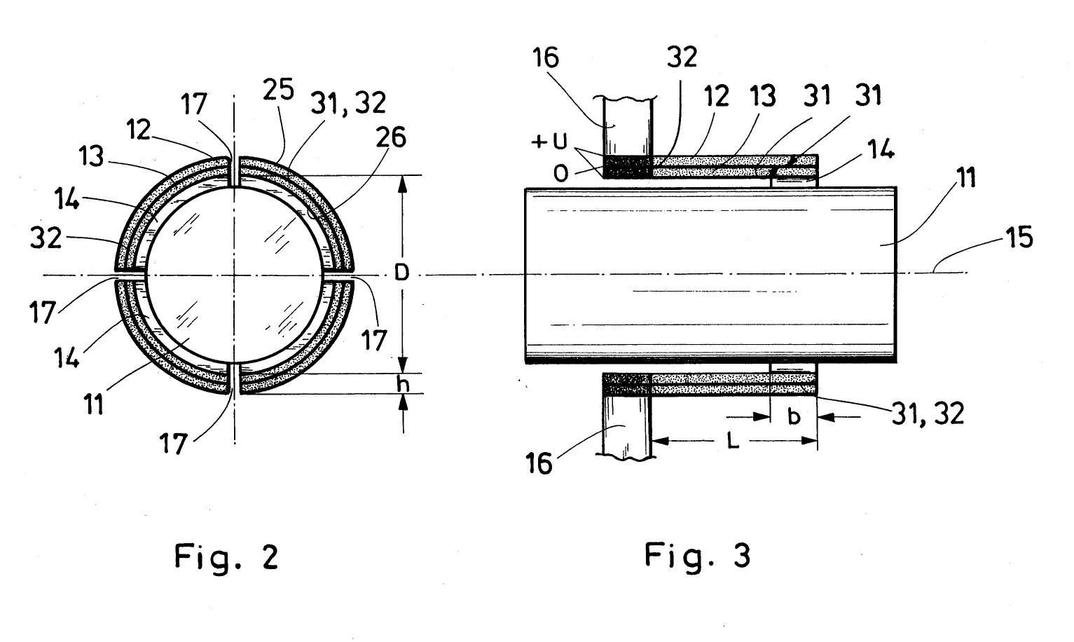

In contrast, the clamping mechanism provided according to the invention is considerably more reliable and can also be used at low temperatures. See FIGS. 2 and 3 in particular for further explanation.

In accordance with the invention, the exemplary embodiment in FIGS. 2 and 3 uses a slitted cylinder or a slitted tube, which has a piezoelectric material made of two layers in the area of the clamping of the movement body 11.

FIG. 2 shows a schematic side view of a clamping mechanism according to the invention of a piezoelectric apparatus. FIG. 3 shows a schematic sectional representation of the embodiment according to FIG. 2 or a part of a piezoelectric motor according to the invention in a rotation of 90°.

It can be seen that, instead of a simple piezo tube for clamping, a double piezo tube (or a piezo tube made of two piezo layers) with a collar 14 is used, wherein the two-layer piezo tube, which is also called a bimorph, comprises an outer piezo tube 12 and an inner piezo tube 13, which are connected together at a contact surface 31. In fact, a middle electrode 32 is provided in this exemplary embodiment on the contact surfaces 31 of the outer piezo tube 12 and the inner piezo tube 13. An outer electrode 25 and an inner electrode 26 are also provided.

The two-layer piezo tube is provided on the one end with a holder 16, which enables an immobilization of the position of the piezo tube. The slits 17 with a length L can be provided as shown. However, they can also be shorter or longer. A collar 14 is also provided that is made of a material other than a piezoelectric material in order to reduce for example the friction with the movement body 11. For better visualization, a longitudinal axis 15 is also shown. The holder 16 can be a holding ring. The piezo tube is preferably not slitted along the length of the holding ring. The collar 14 is designed in a length b. The collar 14 is also accordingly slitted.

Both piezo tubes 12 and 13 are poled in the same radial direction. However, these are offset with electrical fields preferably of the same size but in opposite directions. For this reason, the two-layer piezo tube or the embodiment according to FIG. 2 and FIG. 3 functions like a bimorph. Piezo tubes 12, 13 are also conceivable, which are electrically polarized in the opposite manner and to which the same voltage from the direction of the electrical fields is applied.

Under the assumption that the width of the collar b is considerably smaller than the length of the slitted piezo tube, the radial displacement of the piezo tube and thus the radial displacement of the collar 14 can be represented as follows:

$$Δ D = 3 {d}_{31} U \frac{{L}^{2}}{{h}^{2}} \qquad ( 5 )$$

wherein L is the length of the slitted part of the piezo tube and h is the thickness of the piezo tubes 12, 13 lying inside each other or the thickness of the two-layer piezo tube.

Since the radial displacement is proportional to the square of L/h, this can be an order of magnitude larger than in the case of a piezo tube according to the state of the art. For this reason, even hard piezoelectric ceramics can be used that normally have a lower piezoelectric coefficient, for example EBL PZT-8 with a d₃₁ of [symbol] 1.0×10−8 cm/V. A radial displacement of ΔD≈21 μm results when using 400 V and the dimensions L=1 cm, h=0.075 cm.

This is approx. 40 times as large as in the clamping mechanism of the inchworm. In the case of the temperature of liquid helium (4.2 K), the piezoelectric coefficient of PZT-8 is reduced by a factor of 2. In spite of everything, the radial displacement remains at approx. 10 μm, i.e. a factor of 20 larger than in the clamping mechanism of the inchworm with a soft piezoelectric material, i.e. a material that generally has a larger piezoelectric coefficient.

The enlargement of the radial displacement for clamping also triggers the potentially existing problem with respect to the different heat expansion coefficients. The heat expansion coefficient of PZT-8 is 3 to 4×10⁻⁶/K and that of aluminum oxide (alumina), which is a preferable material for the movement body 11, is approximately 2×10⁻⁶/K. The difference is <2×10⁻⁶/K. For a tube with a diameter of 1 cm, the diameter change in an area of 0° K. to 300° K. would thus be less than 6 μm so that the radial displacement changes less than 3 μm. This is much smaller than the radial displacement of the clamp collar 14 through the piezo tubes 12 and 13 of 10 μm.

The effect of the wear and tear is thus also considerably reduced. In the case of wear and tear or abrasive wear of 0.5 μm, the inchworm would no longer function in the above examples. However, this type of abrasive wear would have hardly any effect on the apparatus according to the invention with respect to the clamping of the movement body 11. Moreover, a sapphire or Al₂O₃ or generally aluminum oxide (alumina) can be used as movement body 11 and also as collar 14 so that the abrasive wear is even further reduced.

Since furthermore the radial displacement for the clamping according to the invention is considerably larger, it is also possible to always hold the collar in contact with the shaft or the movement body 11 and without applying a voltage. The apparatus according to the invention should also function properly in this manner. For example, the inner diameter of the collar 14 in a dead-voltage state could be slightly smaller than the outer diameter of the movement body 11 and an opening could only be opened through the application of a corresponding voltage. The opposite voltage would then lead to a strengthening of the pressure of the collar 14 on the movement body 11.

In the exemplary embodiment according to FIG. 2, a sectoring in four sectors, i.e. a slitting of the tube or tubes with four slits 17, is provided. The degree of hardness of this type of embodiment is larger than the degree of hardness in an embodiment with for example six slits but smaller than with for example three slits. For PZT-8 with a Young module of 8.7×10⁶N/cm² with a clamping mechanism, which has a radius of 0.65 cm, a thickness of the two-layer piezo body (thickness of the outer piezo tube 12 plus the thickness of the inner piezo tube 13 and if applicable the thickness of the intermediate layer in the form of the middle electrode 32 and any adhesive) of 0.075 cm and a length L of 1 cm, the hardness would be

$$K \approx 2 , 57 \frac{N}{m} .$$

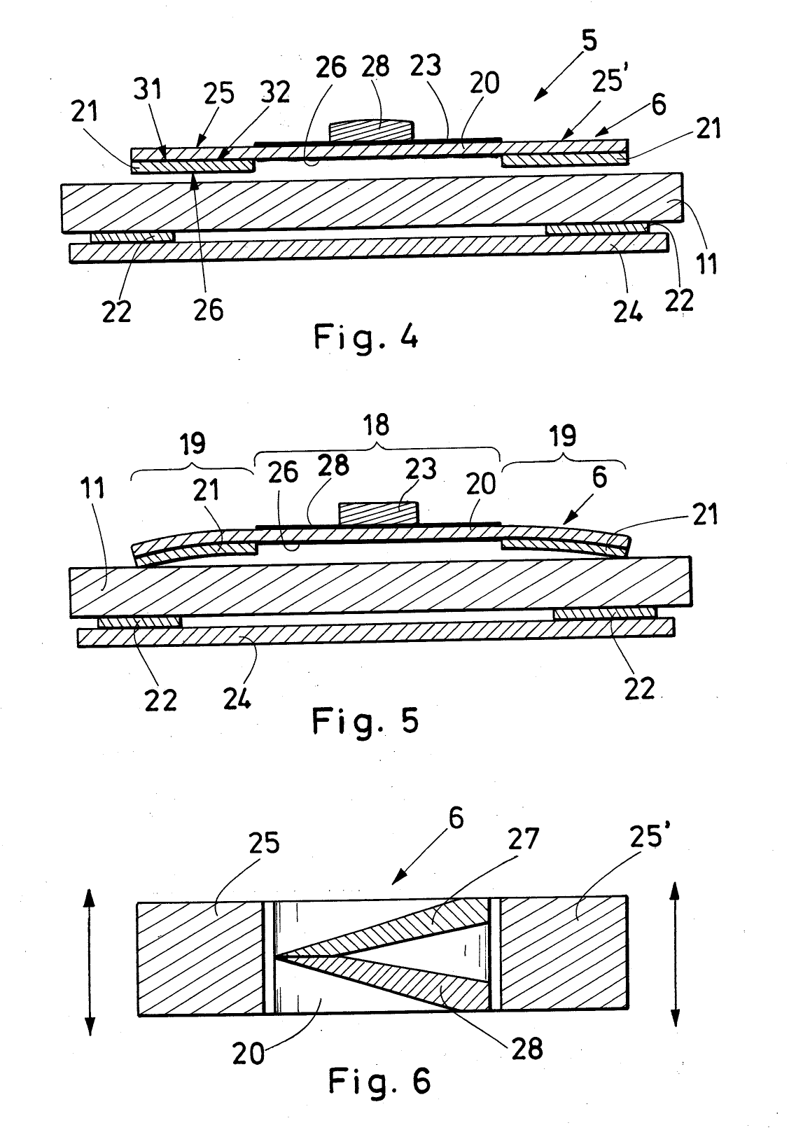

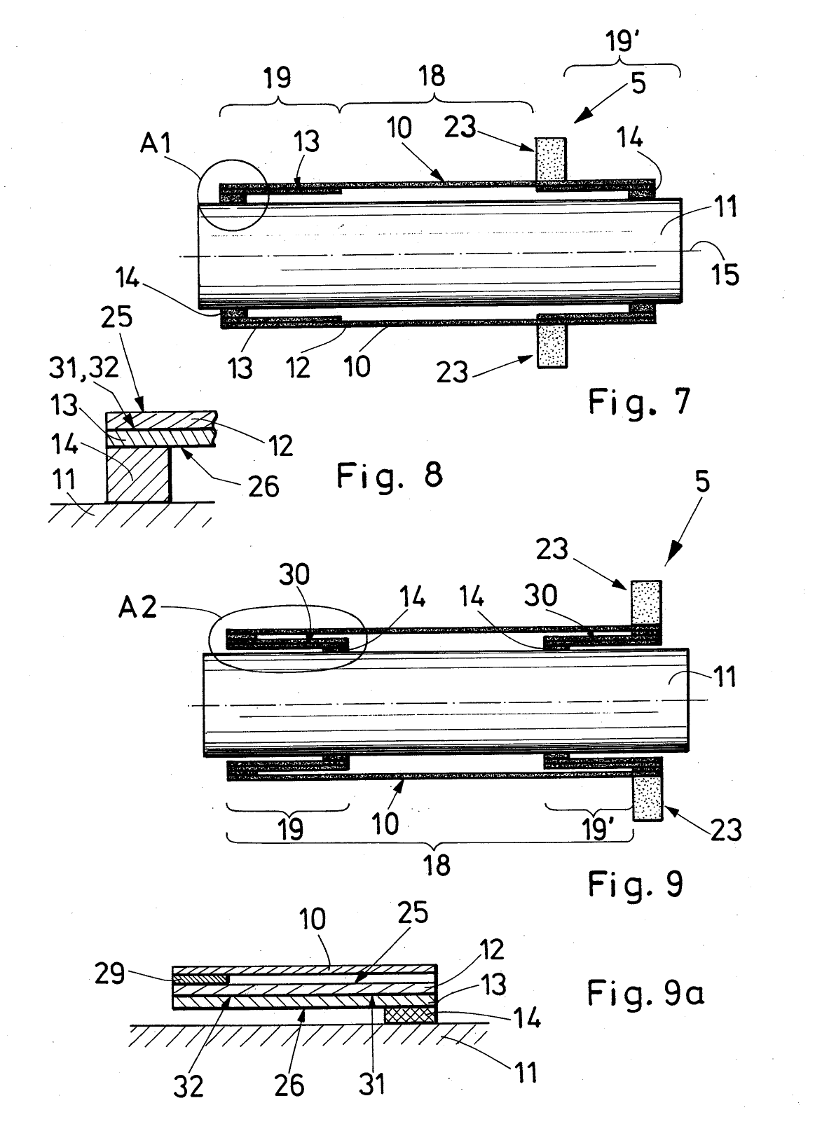

At a liquid helium temperature, the radial displacement is 10 μm. For this reason, the force that can be used is 25 N. The friction coefficient of sapphire on sapphire is 0.2. For this reason, the holding force is 5N. Since two clamping apparatus are provided in the apparatus according to the invention for example according to FIG. 4 through 7 and also according to FIGS. 7, 9 and 11, the apparatus can hold or lift approx. 1 kg of weight. The hardness of the inchworm is somewhat larger, namely typically at 10 N/μm, but the hardness of the piezoelectric apparatus according to the invention is larger than most similar apparatus and in any case sufficient for use in scanning tunneling microscopes and atomic force microscopes as well as in extraterrestrial applications.

FIG. 5 shows a schematic sectional representation of the embodiment of the piezoelectric motor according to the invention, wherein a separation distance is shown between the piezoelectric apparatus 6 comprising the piezo rod 20 and the two inner piezo bodies 12 and the movement body 11 for better visualization. A representation was selected in which no electric voltage is applied to the piezo elements. The movement body 11 is mounted on two mounts 22, which are connected with a base plate 24. FIG. 6 shows a corresponding schematic sectional representation according to FIG. 5, wherein however an electrical voltage is applied to both ends of the piezoelectric apparatus 6 so that a deflection of the end areas 19 takes place. In the middle area 18, the piezoelectric apparatus 6 is immobilized with a holder 23. A longitudinal and axial movement of the movement body 11 in the drawing page of FIG. 5 and FIG. 6 to the left or to the right can occur in a conventional manner as with an inchworm. The deflection of the end areas 19 based on the application of voltage is generally very nicely represented in the publication Chen, C. J., Introduction to Scanning Tunneling Microscopy, Oxford University Press, 1993, page 223, 224.

FIG. 8 shows a schematic view from the top of the piezoelectric apparatus 6 from FIGS. 5 and 6. In particular, the two first electrodes 25 and 25′ are shown, which serve to clamp the movement body 11 or to release the movement body 11. Moreover, a first oblique electrode 27 and a second oblique electrode 28 are shown, which are arranged in the middle area of the piezo rod 20. The piezo rod 20 can, as shown in this example, be entirely made of a piezoelectric material and can also be one piece, as shown in the examples in FIGS. 5 through 7. However, the piezo rod can also be made of several piezoelectric bodies or body parts or pieces or be connected together in this manner. Finally, another material that does not show the piezo effect can be used between the piezoelectric bodies. Moreover, the piezo rod 20 can be made of another material in the area, which is not covered by an electrode.

The oblique electrodes 27 and 28 are arranged mirror-symmetrical to the longitudinal axis of the piezo rod 20. If a voltage is now applied to the first oblique electrode 27 and the second oblique electrode 28, which is demodulated, the piezo material arranged in the area of the electrodes 27 and 28 would expand and contract evenly so that a linear movement of the movement body 11 is enabled and namely through a similar process as used for the inchworm.

Through the use of the oblique electrodes 27 and 28, a rotation of the movement body 11 can also be performed if it is pivot-mounted in the mount 22. For this, these types of electrical voltages must be applied to the electrodes 27 and 28 such that the piezo material contracts or expands in the area of the first oblique electrode 27 and expands or contracts in the other direction in the area of the second oblique electrode. During immobilization of the piezo rod 20 on the holder 23, this would lead to a movement of the end pieces 19 of the piezo rod 20 according to the arrows schematically indicated in FIG. 6. The holder 23 is not shown in FIG. 6 for better visualization.

Through the application of an opposite voltage, it is possible to shift the movement body 11 into a rotational movement. It is thus possible to provide a linear movement and a rotational movement of the movement body 11 with the piezoelectric apparatus 6 or the piezoelectric motor 5. The motor 5 according to the invention thus integrates a linear and rotational movement in one single compact design.

FIGS. 7, 9 and 11 show a more elegant and stable embodiment according to the invention. These figures show rotation-symmetrical piezoelectric apparatus 6, which can move a rotation-symmetrical movement body 11 in both a translatory and rotational manner.

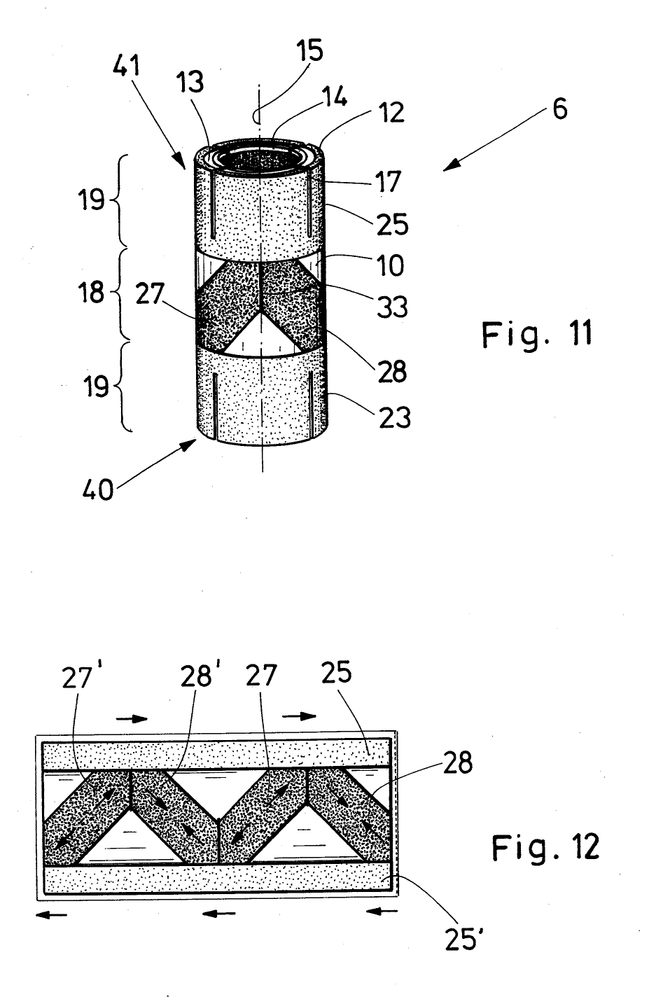

FIG. 7 shows a schematic sectional representation of another embodiment of a piezoelectric motor 5 according to the invention. A piezo tube 10 is provided, which has a middle area 18 of the piezoelectric apparatus 6 and extends into the end areas 19. An inner piezo tube 13 and a collar 14 are arranged in the end area 19 of the piezo tube 10. The piezo tube 10 and the inner piezo tube 13 are designed with slits (not shown) in the end area 19, namely according to for example FIG. 11 or FIG. 2, wherein three slits, two slits, five slits or more slits can also be provided instead of four slits.

Four slits should be assumed for the description of this exemplary embodiment. The holder 23 is not arranged centrally on the piezo tube 10, but rather in the beginning area of an end area of the one side. However, the holder 23 can also be attached at any other location. FIG. 8 shows a schematic representation of section A1 from FIG. 7 for better visualization. In particular, the contact surfaces 31 are also represented there. As in the exemplary embodiment of FIG. 3, a corresponding arrangement of the electrodes can also be provided, i.e. a middle electrode 32 in the area of the contact surfaces 31 and an outer electrode 25 and an inner electrode 26, wherein the polarisation of the piezoelectric material of piezo tube 10 and the inner piezo tube 13 is aligned the same. An opposite polarity is then applied to the electrode in order to achieve a deformation of the two-layer body comprising the bodies 12 and 13. However, an opposite polarization of the piezoelectric material can also be provided and a demodulated or rectified voltage can be applied in order to achieve this effect. An embodiment in which an inner electrode is used instead of a middle electrode can also be conceivable. In this case, the polarization of the piezoelectric material in the outer piezo tube and the inner piezo tube should be at least partially counterbalanced.

In this exemplary embodiment, an electrical potential for example of +U is applied to the outer electrode 25 and the inner electrode 26 and of 0 to the middle electrode 32.

The apparatus according to the invention have the advantage that both end areas can exert a pressure on the movement body 11, however one side has a greater pressure than the other side, so that in the case of a length change in the middle area of the piezo tube 10 or in the case of a rotation of this middle area, the side of the movement body 11 slides through the clamp, on which a lower force or a lower pressure is exerted. This enables a very exact and reliable movement of the movement body 11.

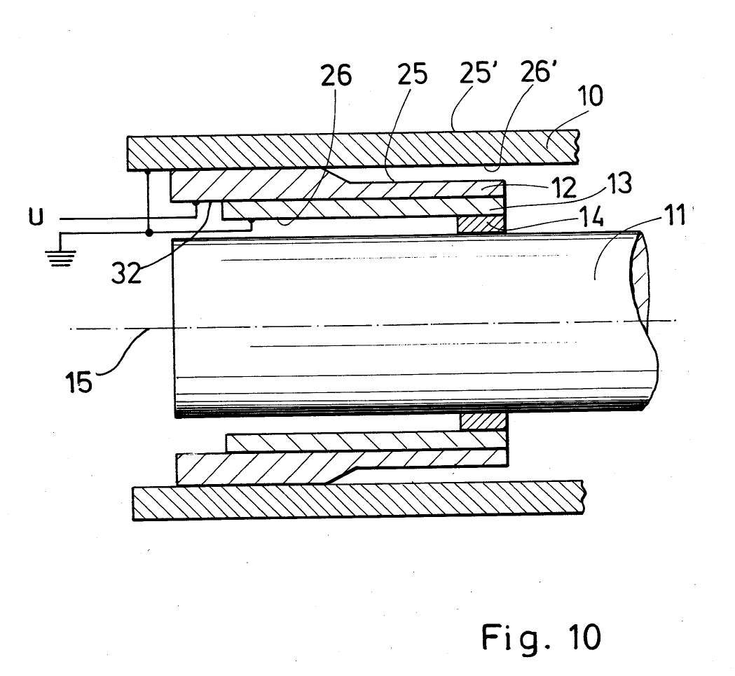

FIG. 9 shows a schematic sectional representation of a somewhat different embodiment according to the invention of a piezoelectric motor 5, wherein the piezo tube 10 can only contribute to the transverse or rotational movement of the movement body 11, since the part of the piezoelectric apparatus 6, which is provided for the clamping of the movement body 11, is attached to the piezo tube 10 within the piezo tube 10 with a spacer or a connection piece 29. FIG. 10 shows a schematic sectional representation of section A2 from FIG. 9 for better visualization. Electrodes, which ensure a rotational movement and/or a translatory movement, can be provided over the entire piezo tube 10. The holder 23 can also be arranged at a different location, for example in the middle of the piezo tube 10.

The exemplary embodiment according to FIG. 7 thus uses a long piezo tube 10 for the movement of the movement body 11 and the outer area of the tube 10 for the clamping mechanism. The two inner piezo tubes 13 are glued onto the inside of the long piezo tube 10 in the area of the outer piezo tube 12 together with the collar or the collars 14. The two-layer body, which comprises the inner piezo tube 13 and the outer piezo tube 12, is correspondingly at least partially slitted, namely longitudinally and axially to the longitudinal axis 15. Three or four sectors are preferably used. The embodiment according to FIG. 9 uses two separate bimorphs or two-layer bodies and a long piezo tube 10, which is responsible for the movement. Within the framework of the invention, a two-layer body is understood as a body with at least two piezoelectric layers.

The inner piezo tube 13 and the outer piezo tube 12 are normally glued together before fastening on the piezo tube 10 according to FIG. 9. The corresponding slits are also made before being fitted in the piezo tube 10. An electrical contact of the electrodes of the outer and the inner piezo tube 12 and 13 can occur via corresponding openings, which are preferably provided through the connection piece 29 or the connections pieces 29 and the collar 14 (for example through the slits).

FIG. 11, which shows a schematic three-dimensional representation of another embodiment of a piezoelectric apparatus 6 according to the invention for use in a piezoelectric motor 5, serves to explain the rotational movement and also to make possible a translatory movement in the case of obliquely arranged electrodes in the middle area 18 of the piezoelectric apparatus 6. The middle area 18 can extend into the end areas 19.

As in the previous examples, slitted end areas 19 are provided, which have an outer piezo tube 12, an inner piezo tube 13 and a collar 14. The first electrode 25 is also shown in the upper area in FIG. 11 and a first electrode 25′ is shown in the bottom area. The corresponding counter electrodes are also available and furthermore each with a middle electrode. However, these are not provided with reference numbers in FIG. 11 for the sake of better clarity. Furthermore, the movement body 11 is also not shown. The upper end area 19 defined an upper clamp 41 and the lower end area 19 defines a lower clamp 40. In the middle area 18 of the piezo tube 10, which can be designed as one piece with the outer piezo tubes 12 but can also be connected with them, four oblique electrodes are provided, of which only two are visible due to the representation in FIG. 11, namely a first oblique electrode 27 and a second oblique electrode 28. A borderline 33, which isolates the two electrodes from each other, is defined between the two oblique electrodes 27 and 28.

FIG. 12 is a view from the top of part of the piezoelectric apparatus 6 from FIG. 11 in the rolled up state. Part of the upper first electrode 25 and the bottom first electrode 25′ is shown and two first oblique electrodes 27 and 27′ and two second oblique electrodes 28 and 28′ are shown.

The functionality for the rotational movement can be better understood in FIG. 12. The oblique electrodes 27, 27′, 28 and 28′ are spiral, as can be clearly seen in FIG. 12. The first oblique electrodes 27 and 27′ are oriented opposite the second oblique electrodes 28 and 28′. The surfaces left in white in FIGS. 11 and 12 are not provided with electrode material. In order to create a rotation, voltages are applied to the first oblique electrodes 27, 27′ and the second oblique electrodes 28, 28′, which are opposite, so that the first oblique electrodes expand, for example as indicated by the arrows in FIG. 12, and the second oblique electrodes 28 and 28′ contract, as also indicated accordingly by the arrows. This results in a movement of the upper end area or the upper clamp 41 to the right in the plane of FIG. 12 and a movement of the bottom clamp 40 to the left, i.e. a rotation of the upper and the lower clamp in FIG. 11.

Through the piezoelectric motor according to the invention, it is possible even in the case of not extremely round movement bodies 11 and accordingly round piezo tubes to provide a rotation of the movement body 11. The radial displacement can be in the range of several tenths of pm so that a fast rotational movement is also possible. Since the rotational movement does not depend on friction and impulse as in the state of the art, high stability and reliability and accuracy are also possible.

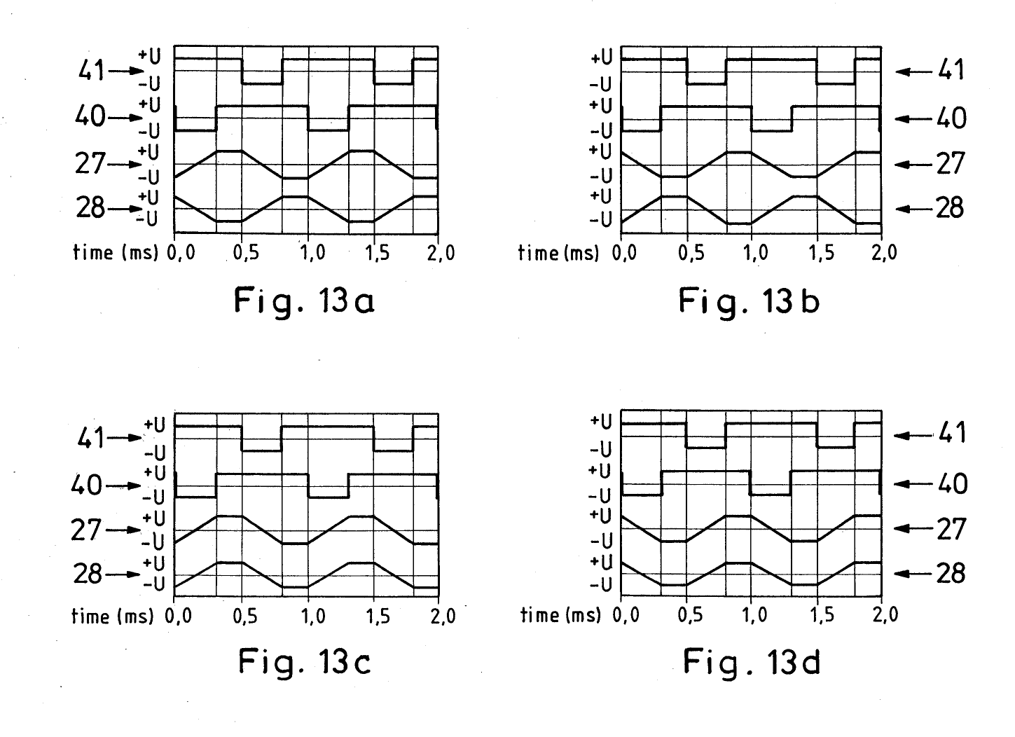

FIG. 13 shows schematic voltage-over-time diagrams, which specify the application of voltages to the clamp electrodes 25, 25′ or 26, and namely subdivided into electrodes of the bottom clamp 40 and the upper clamp 41. Moreover, the voltages applied to the oblique electrodes 27 or 27′ and 28′ are indicated. With the voltage sequence according to FIG. 13a, a clockwise rotation is possible and, with a voltage progression according to FIG. 13b, a counter clockwise rotation is possible. With a voltage progression according to FIG. 13c, the approach of the tip of a scanning tunneling microscope to the specimen is for example enabled and, with a voltage progression according to FIG. 13d, the removal of the tip from the specimen, i.e. a translatory movement in both cases.

It is also possible to simultaneously create a rotational and translatory movement with each step. For this, the oppositely polarized voltages, which are applied to the respectively neighboring and differently arranged oblique electrodes, must be different in size.

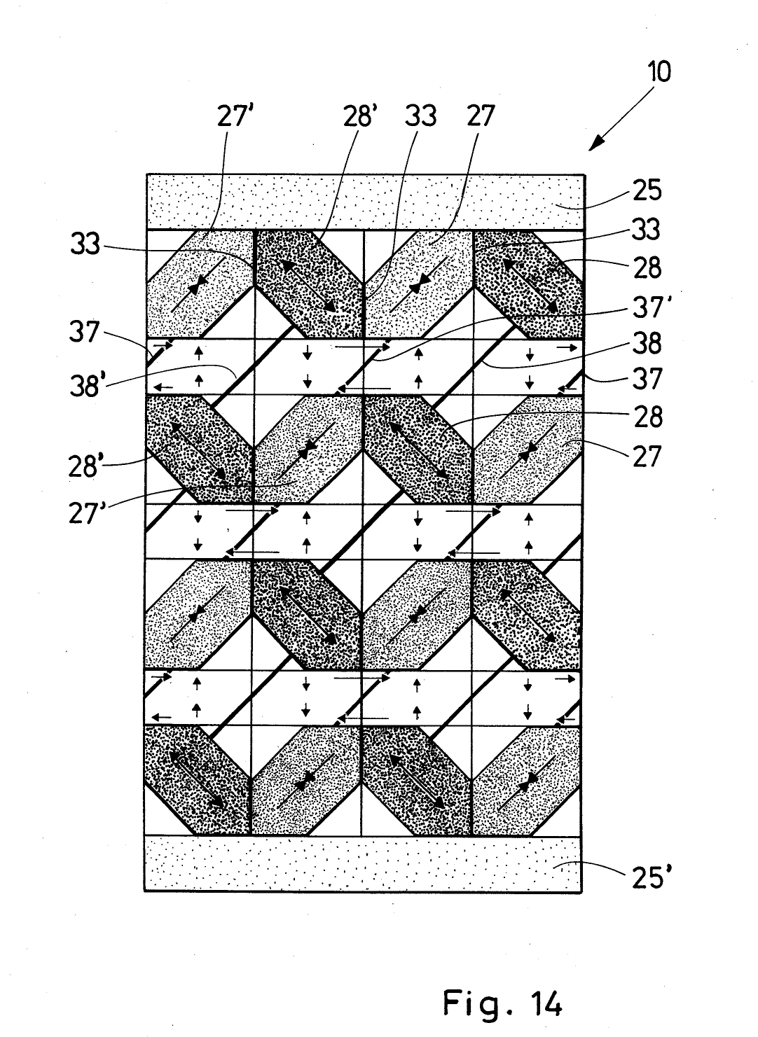

FIG. 14 shows another embodiment of a piezoelectric apparatus 6 according to the invention, in which the lateral surface of a corresponding piezo tube is also rolled up in the drawing plane of FIG. 14 and, also as in the previous example according to FIG. 12 , only part of the upper first electrode 25 and part of the lower first electrode 25′ is shown.

It can be seen that in the longitudinal and axial direction of the piezo tube 10 four quadrupoles of oblique electrodes are arranged behind each other, wherein four oblique electrodes are each arranged next to each other diagonal to the longitudinal axis. Areas are also provided, which are mainly provided with no electrode material, but with electrode connections 37 and 37′ and 38 and 38′. The electrode connection 37 connections the first oblique electrode 27, which are arranged behind each other in the longitudinal and axial direction, and the electrode connection 37′ the first oblique electrode 27′. The same goes for the electrode connection 38 to the second oblique electrodes 28 and 38′ to the second oblique electrodes 28′.

The corresponding arrows are also shown, which exist for a rotational movement or a rotational displacement of the bottom clamp 40 and the upper clamp 41 through the corresponding application of electrical voltage to the piezo tube 10.

The angle speed of the rotation can be calculated accordingly. It is assumed that a PZT-4 material of Staveley sensors with a piezoelectric constant d₃₁=0.135 nm/V with a thickness of the piezo tube of 0.75 mm and a diameter of 12.7 mm and a maximum voltage of U=250 V is used. In this case, the linear displacement for each period T is x [symbol] is 1.8 μm. In the case of a frequency of 1 kHz, the rotor thus moves 1.8 mm. This results in an angle speed of approximately 2.6°/s. Accordingly, a speed of 1.8 mm/s is to be assumed in the case of the linear movement or in the case of the transverse movement at 1 kHz. Control of both the rotational movement speed and the linear movement speed is possible.

A variation of the embodiment according to FIG. 14 can also be provided, such that for example two four-part groups of oblique electrodes are arranged and used for the rotational movement and two of these groups for the translatory movement. For this, the electrode connections would have to be separated for example in the middle between the first electrode 25 and the first electrode 25′.

The object of the invention can be used wherever the so-called inchworm made by the company EXFO, previously Burleigh, USA, is used. The invention can thus be used for highly precise translation positioning in the range of mm and μm. This considerably expands the range of uses, in particular through low temperature suitability. Entirely new uses can also be developed through which additional capability, highly precise rotational movements with the possibility of very small increments can be executed. This allows use in the field of nanotechnology. Since the motor is does not need any lubricant, it is particularly advantageous for use in an ultra high vacuum, for example in the field of scanning tunneling microscopy. There are also applications in the field of aviation and space travel. According to the invention, only one single apparatus is needed to enable a stable and reliable rotational and translatory movement of a movement body.

What is claimed is:

1. A piezoelectric movement device, in particular a motor, said piezoelectric movement device comprising: a piezoelectric apparatus, having a middle area and two end areas, and with a movement body, which is mounted on or in, a mount or, the piezoelectric apparatus, wherein one end area is adapted to or both end areas are adapted to exert a force in the direction of the movement body, said force being exerted transversely of an axis to a longitudinal axis of the piezoelectric apparatus, on the movement body, the middle area being a piezoelectric body and the end areas each comprising two piezoelectric bodies, connected with each other, via contact surfaces.

2. A piezoelectric movement device according to claim 1, wherein the normals or measurement standards of the contact surfaces are arranged substantially parallel to the direction of the exerted force.

3. A piezoelectric movement device according to claim 1, wherein an electrode is arranged between the two piezoelectric bodies of the end areas.

4. A piezoelectric movement device according to claim 1, wherein an intermediate body made of a different material than the piezoelectric body is provided on at least one piezoelectric body of an end area on the surface, which is arranged next to the movement body.

5. A piezoelectric movement device according to claim 1, wherein the mount is part of the piezoelectric apparatus.

6. A piezoelectric movement device according to claim 1, wherein the piezoelectric apparatus is a long hollow body open on the end areas.

7. A piezoelectric movement device according to claim 6, wherein the hollow body is a, in particular cylindrical, tube.

8. A piezoelectric movement device according to claim 1, wherein the piezoelectric apparatus is slit longitudinally with respect to the axis in the end areas.

9. A piezoelectric movement device according to claim 1, wherein the middle area of the piezoelectric apparatus has at least one electrode, which is arranged obliquely to the longitudinal axis of the piezoelectric apparatus.

10. A piezoelectric movement device according to claim 9, wherein electrodes are arranged obliquely to the longitudinal axis of the piezoelectric apparatus, and are arranged in the longitudinal and axial direction in at least one of behind each other and next to each other in a substantially perpendicular manner.

11. A piezoelectric movement device according to claim 9, wherein the movement body is pivot-mounted.

12. A piezoelectric movement device according to claim 9, wherein at least one electrode is spiral-shaped at least in sections.

13. A piezoelectric movement device according to claim 10, wherein at least two electrodes are arranged symmetrically around a plane, which comprises the longitudinal axis and a common borderline.

14. A piezoelectric movement device according to claim 1, wherein the piezoelectric body of the middle area is one piece with a piezoelectric body of an end area.

15. A piezoelectric movement device according to claim 1, operable to cause at least one of a translatory and rotary movement of the movement body.

16. A method for the manipulation of a movement body in or on a piezoelectric movement device according to claim 10, wherein similar or codirected electrical potentials are applied to the electrodes of the middle area for the longitudinal and axial expansion or shortening of the middle area of the piezoelectric apparatus.

17. A method for the manipulation of a movement body in or on a piezoelectric movement device according to claim 10, wherein the electrodes in the middle area of the piezoelectric apparatus are arranged relative to the longitudinal axis in at least one of a transverse and radial manner next to each other are supplied with locally alternating electrical potentials for the rotation of the movement body.
